(19) United States
(12) Patent Application Publication
(10) Pub. No.: US 2007/0291336 A1
(43) Pub. Date: Dec. 20, 2007

(54) Image adjusting device

(75) Inventors: Kai-Hsiang Hsu, Tucheng City (TW); Yi-Chia Shan, Jhongli City (TW); Tsan-Hung Tsai, Sanchong City (TW); Hsu-Chia Kao, Pingjhen City (TW)

Correspondence Address: BIRCH STEWART KOLASCH & BIRCH, PO BOX 747, FALLS CHURCH, VA, 22040-0747, US

(73) Assignee: MARKETECH INTERNATIONAL CORP.

(21) Appl. No.: 11/729,804

(22) Filed: Mar. 30, 2007

(30) Foreign Application Priority Data
Jun. 14, 2006 (TW) 095121150

(51) Int. Cl. G03F 3/00

(52) U.S. Cl. 358/520; 358/518; 358/523

(57) ABSTRACT

The invention relates to an image adjusting device applied to a display system. According to a color area selected by the user, the image adjusting device is used for adjusting the saturation (or the lightness) of the pixels of an input image. Accordingly, the user can clearly see the color included in the selected color area being located within which section of the image.

### BACKGROUND OF THE INVENTION

1. Field of the Invention

The invention relates to an image adjusting device and, more particularly, to an image adjusting device which can temporarily change the image parameters (e.g. lightness or saturation) of the pixels of an input image according to the user-selected color area. Accordingly, the user can clearly see which section of the image is the color in the selected color area located in.

2. Description of the Prior Art

When looking at an image, the user often desires to adjust some of the colors in the image. For example, the user may try to make the sky in the image bluer or the grasslands greener. In general, these adjustable image parameters comprise lightness, hue, and saturation.

In order to process the color of an image, the signal of the image must be converted from the original color space (e.g. RGB) to the color space (e.g. YCbCr, YUV, CIELab, etc.) where the lightness (Y) and the colors (C) are separated. Then, the information about the lightness, the hue, and the saturation of the image can be obtained. Referring to FIG. 1, FIG. 1 is a schematic diagram of Lab color space. In the example of Lab color space, L represents the scale of light intensity, and a and b represents the color scale. As shown in FIG. 1, the lightness (L) is controlled by height, the hue (H) is controlled by angle, and the saturation (S) is controlled by radius.

Referring to FIG. 2, FIG. 2 is a schematic diagram of the hue being divided into six color areas according to the prior art. The distribution of the hue ranges from 0° to 360° in the Y/C separated color space. The distribution of the hue can be divided into several color areas with different range of the angles according to practical needs. For the conventional monitors, the user can use on screen display (OSD) to adjust the color by selecting the system divided color area. In order to allow the user to easily adjust the color, the designer can name each color area according to the color it covers. However, the user usually still does not know the color he/she wants to adjust belongs to which color area or certain color area contains which colors. In other words, it is inconvenient for the user to adjust color if he/she is unable to know which section of the image is the color, included in the selected color area, located in.

Therefore, the main scope of the invention is to provide an image adjusting device to solve the above problems.

### SUMMARY OF THE INVENTION

A scope of the invention is to provide an image adjusting device which can temporarily change the image parameter (e.g. lightness or saturation) of the pixels of an input image according to the user-selected color areas. Therefore, the user can clearly see which section of the image is the color, included in the selected color area, located in.

According to a preferred embodiment of the invention, the image adjusting device of the invention, applied to a display system, is used for adjusting the saturation (or lightness) of a pixel of an input image according to a user-selected color area. If the color areas of the display system are obtained by dividing the hue in a color space having lightness separated from colors, then the hue of each pixel of an input image belongs to one of the respective divided color areas.

The image adjusting device comprises a memory unit, a judgment module, a multiplexer, and a multiplicator.

The memory unit is used to store at least one first gain and a second gain. The judgment module can judge whether the user-selected color area is the same as the color area that includes the hue of a certain pixel.

The multiplexer will output one first gain when the user-selected color area is the same as the color area that includes the hue of a certain pixel. Then, the multiplicator will multiply the value of saturation (or lightness) of the pixel by the first gain. On the contrary, the multiplexer will output the second gain when the user-selected color area is different from the color area that includes the hue of a certain pixel. Afterward, the multiplicator will multiply the value of saturation (or lightness) of the pixel by the second gain. In this embodiment, the first gain is between 0 and 1, and the second gain is set as 1.

For example, when the user selects the green color area, and the hue of an input image belongs to green pixels, the value of saturation (or lightness) will be multiplied by a gain less than 1. This makes the color lighter. In contrast, if the hue of an input image does not belong to green pixels, the value of saturation (or lightness) will be multiplied by 1. This results in unchanged color. By doing so, the user can clearly determine which section of the image is the color included in the selected color area located in.

Besides, the color areas of the display system can be also obtained by dividing two chroma components or the hue/saturation in a color space having lightness separated from colors. It depends on practical application.

The advantage and spirit of the invention may be understood by the following recitations together with the appended drawings.

### BRIEF DESCRIPTION OF THE APPENDED DRAWINGS

The patent or application file contains at least one drawing executed in color. Copies of this patent or patent application publication with color drawing(s) will be provided by the office upon request and payment of the necessary fee.

FIG. 1 is a schematic diagram of the Lab color space.

FIG. 2 is a schematic diagram of the hue being divided into six color areas according to the prior art.

FIG. 3 is a functional block diagram of the display system according to a preferred embodiment of the invention.

FIG. 4 is a schematic diagram of the color areas of the display system obtained by dividing the hue in a color space having lightness separated from colors.

FIG. 5 is a functional block diagram of the image adjusting device shown in FIG. 3.

FIG. 6A and FIG. 6B are schematic diagrams of selecting color area and adjusting image parameter respectively.

FIG. 7A is the displayed image of the input image.

FIG. 7B is the displayed image of the input image in FIG. 7A when the user selected green color area.

FIG. 8 is a schematic diagram of the color area of the display system obtained by dividing the chroma components in a color space having lightness separated from colors.

FIG. 9 is a schematic diagram of the color area of the display system obtained by dividing the hue and the saturation in a color space having lightness separated from colors.

FIG. 10 is a functional block diagram of the image adjusting device according to another preferred embodiment of the invention.

FIG. 11A and FIG. 11B are schematic diagrams of the look-up table shown in FIG. 10.

FIG. 12 is a schematic diagram of the look-up table according to another preferred embodiment of the invention.

FIG. 13 is a schematic diagram of the look-up table according to another preferred embodiment of the invention.

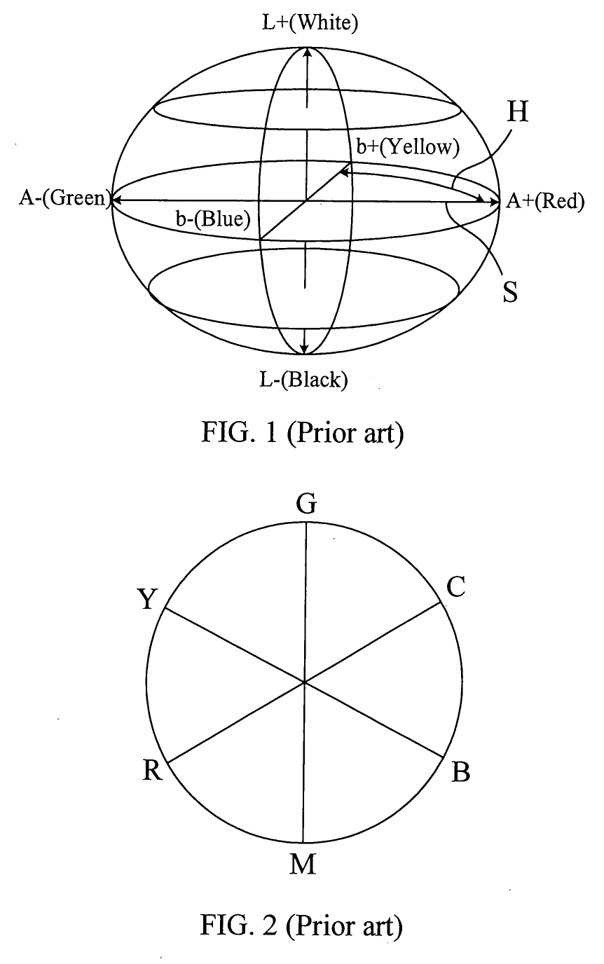

### DETAILED DESCRIPTION OF THE INVENTION

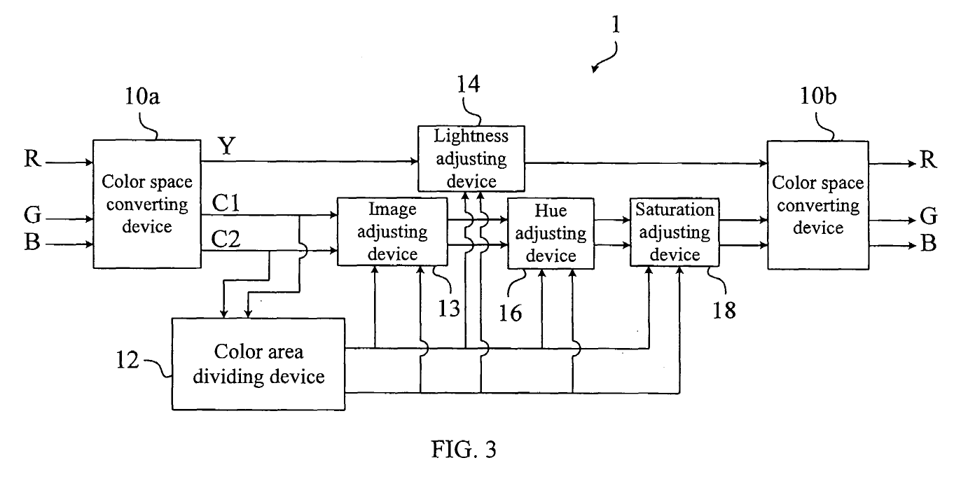

Referring to FIG. 3, FIG. 3 is a functional block diagram of a display system 1 according to a preferred embodiment of the invention. The display system 1 comprises color space converting devices 10a, 10b, a color area dividing device 12, an image adjusting device 13, a lightness adjusting device 14, a hue adjusting device 16, and a saturation adjusting device 18.

The image adjusting device 13 of the invention, applied to the display system 1, is used to adjust a first image parameter (lightness or saturation) of the pixels of an input image according to the user-selected color areas. The invention can be applied to all color spaces having lightness separated from colors, such as YCbCr, YUV, CIELab, etc. In this embodiment, the color space converting device 10a of the display system 1 will convert the image signal from the original color space (e.g. RGB) to the color space (e.g. CIELab) having lightness separated from colors. Then, the information about the lightness Y, the chroma components C1, C2, the hue, and the saturation of the image can be obtained.

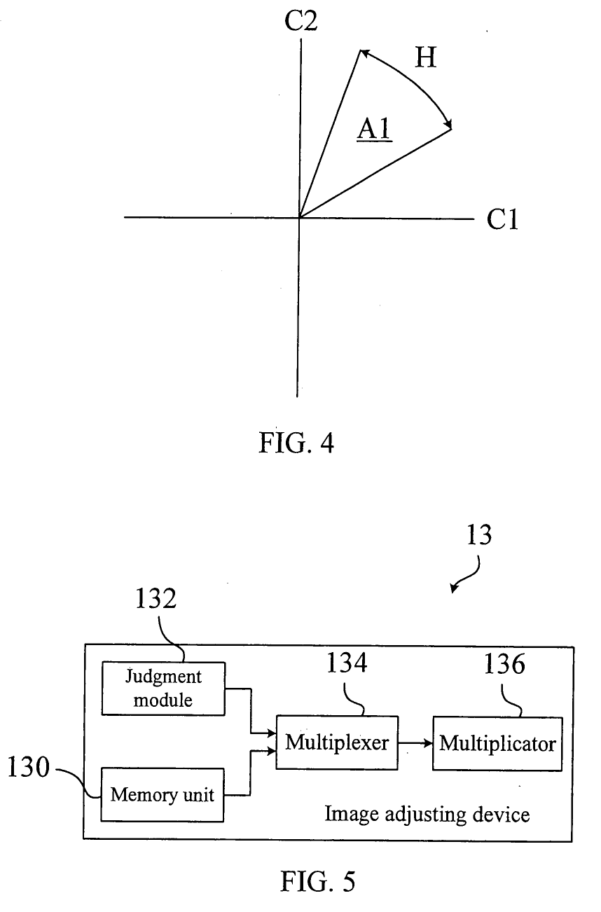

Referring to FIG. 4, FIG. 4 is a schematic diagram of the color areas of the display system obtained by dividing the hue in a color space having lightness separated from colors. In this embodiment, the color areas of the display system 1 can be obtained by dividing the hue using the color area dividing device 12. As shown in FIG. 4, the range of the color area A1 is where the metric hue angle H is larger than 30° and less than or equal to 70°.

Referring to FIG. 5, FIG. 5 is a functional block diagram of the image adjusting device 13 shown in FIG. 3. The image adjusting device 13 comprises a memory unit 130, a judgment module 132, a multiplexer 134, and a multiplicator 136. The memory unit 130 is used to store one first gain and one second gain. In this embodiment, the first gain is between 0 and 1, and the second gain is set as 1.

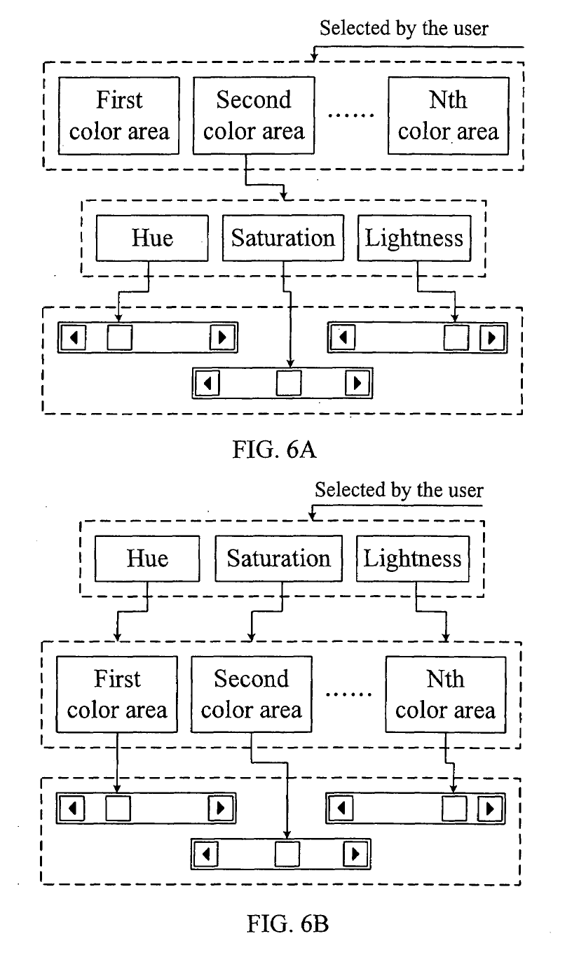

Referring to FIG. 6A and FIG. 6B, FIG. 6A and FIG. 6B are schematic diagrams of selecting color area and adjusting image parameter respectively. As shown in FIG. 6A, the user can first select the color area he/she wants to adjust, and then select the image parameter he/she wants to adjust. As shown in FIG. 6A, the user can also select the image parameter he/she wants to adjust first and then select the color area he/she wants to adjust.

After the color area is selected by the user, the judgment module 132 will judge whether the user-selected color area is the same as the color area where the hue of a certain pixel belongs to. When the user-selected color area is the same as the color area where the hue of certain pixel belongs to, the multiplexer 134 will output the first gain. Afterward, the multiplicator 136 will multiply the value of saturation (or lightness) of the pixel by the first gain outputted by the multiplexer 134. On the contrary, the multiplexer 134 will output the second gain when the user-selected color area is different from the color area where the hue of certain pixel belongs to. Then, the multiplicator 136 will multiply the value of saturation (or lightness) of the pixel by the second gain outputted by the multiplexer 134.

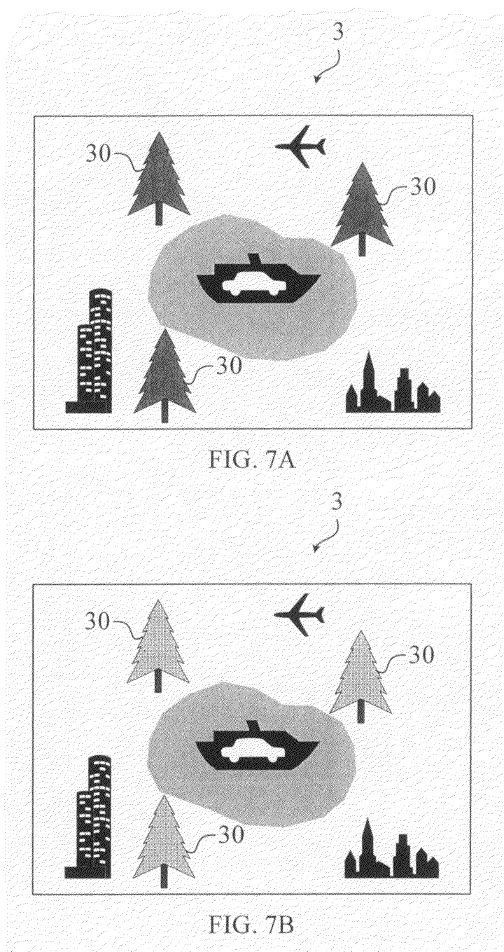

Referring to FIG. 7A and FIG. 7B, FIG. 7A shows the displayed image of the input image 3. FIG. 7B shows the displayed image of the input image 3 when the green color area selected by the user. For instance, if the user selects the green color area, the pixels of the input image 3, whose hue belongs to green, and their value of saturation (or lightness) will be multiplied by a gain less than 1. This will make the color lighter. In contrast, if the pixels of the input image 3, whose hue does not belong to green, and their value of saturation (or lightness) will be multiplied by 1. The color will stay unchanged. In this way, the user can clearly see the color included in the selected color area being located within which section of the image. The user can further adjust the color of the image on the screen to a satisfying condition.

It should be noticed that the above changes of saturation (or lightness) is temporary. The image will recover to its original condition when the user make the next step of adjustment or leave the selection of the color area.

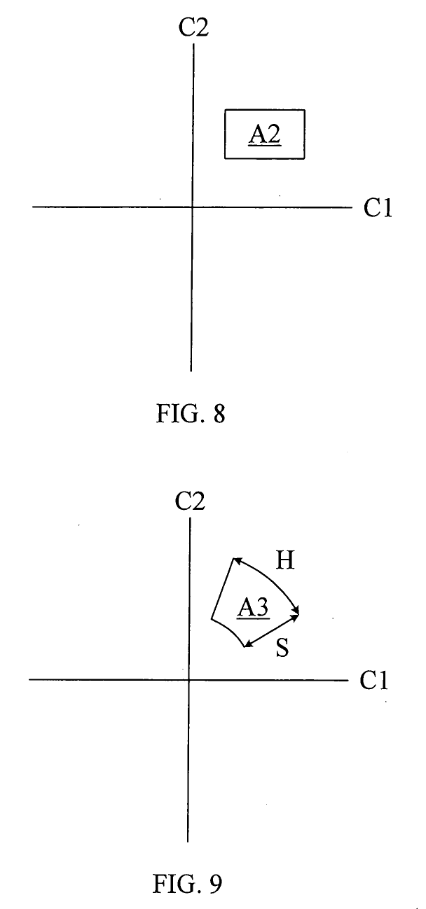

Referring to FIG. 8, FIG. 8 is a schematic diagram of the color area of the display system obtained by dividing the chroma components in a color space having lightness separated from colors. In another preferred embodiment of the invention, the color area of the display system 1 can also be obtained by dividing the chroma components in a color space having lightness separated from colors by the color area dividing device 12. As shown in FIG. 8, the range of the color area A2 is where the chroma component C1 larger than 20, and less than or equal to 50, or the chroma component C2 is larger than 30, and less than or equal to 80. In this embodiment, the judgment module 132 judges whether the user-selected color area is the same as the color area where the chroma components C1, C2 of certain pixels belongs to.

Referring to FIG. 9, FIG. 9 is a schematic diagram of the color area of the display system obtained by dividing the hue and the saturation in a color space having lightness separated from colors. In another preferred embodiment of the invention, the color area of the display system 1 can also be obtained by dividing the hue and the saturation by the color area dividing device 12. As shown in FIG. 9, the range of the color area A3 is where the metric hue angle H is larger than 30° and less than or equal to 70°, and where the saturation S is larger than 50 and less than or equal to 100. In this embodiment, the judgment module 132 judges whether the user-selected color area is the same as the color area where the hue and the saturation of certain pixels belong to.

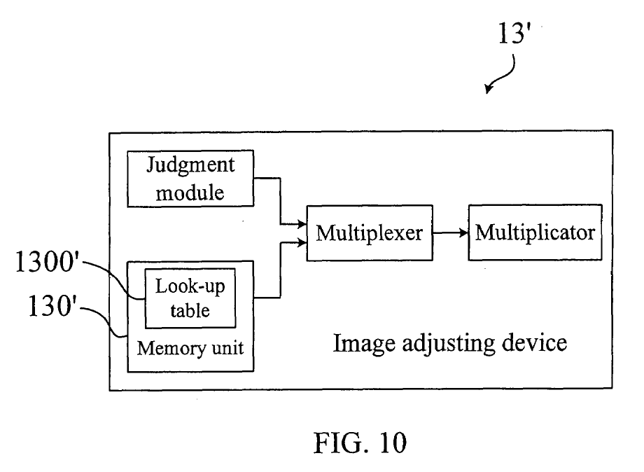

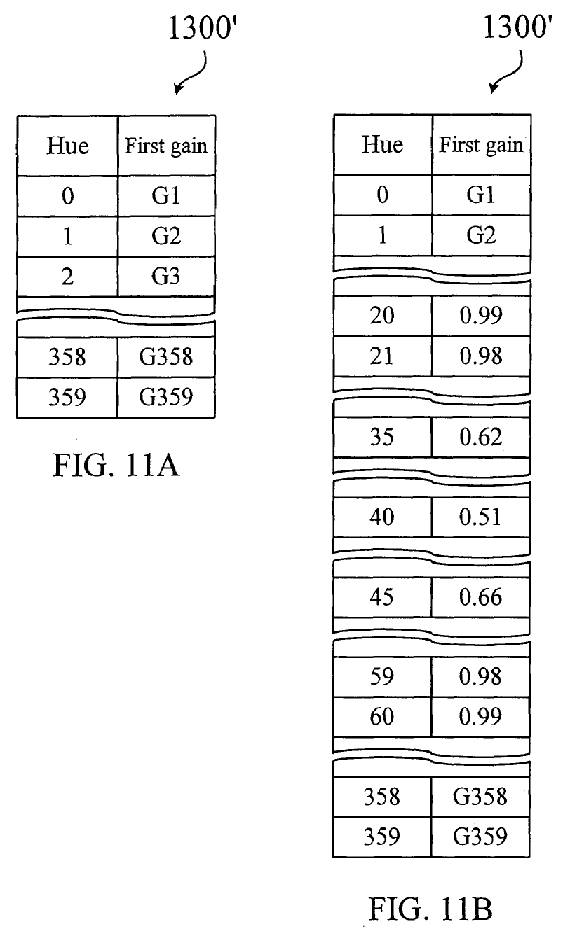

Referring to FIG. 10 and FIG. 11, FIG. 10 is a functional block diagram of the image adjusting device 13′ according to another preferred embodiment of the invention. FIG. 11A and FIG. 11B are schematic diagrams of the look-up table 1300′ shown in FIG. 10. The main difference between the image adjusting device 13′ and the image adjusting device 13 is that the memory unit 130′ of the image adjusting device 13′ further stores a look-up table 1300′. In this embodiment, the look-up table 1300′ records 360 hues and 360 first gains, and each of the hues corresponds to one of the 360 first gains respectively. Compared to the first embodiment, the image adjusting device 13′ in the invention can use the look-up table 1300′ to provide different gains according to the different hues in the same color area, forming the saturation (or the lightness) gradient. In other words, the multiplexer will output the first gain corresponding to the hue of the pixel when the user-selected color area is the same as the color area where the hue of a certain pixel belong to. For example, if the range of the red color area is between 20° and 60°, the look-up table 1300′ can be set as shown in FIG. 11B. By doing so, the saturation (or the lightness) will show gradient effect. The functional theorem of the image adjusting device 13′ in FIG. 10 is the same as the image adjusting device 13 shown in FIG. 5, so the details are not further described.

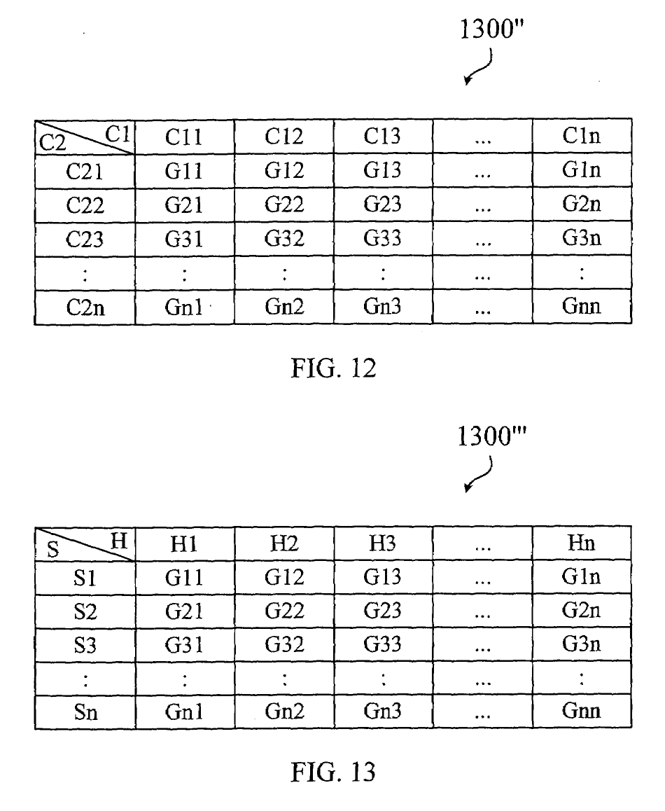

Referring to FIG. 12, FIG. 12 is a schematic diagram of the look-up table 1300″ according to another preferred embodiment of the invention. In another preferred embodiment of the invention, if the color areas are obtained by dividing the chroma components in a color space having lightness separated from colors, the look-up table 1300″ records the at least one first gain, at least one first chroma component C1, and at least one second chroma component C2; each of the chroma components C1, C2 corresponds to one of the first gains Gnn respectively. The functional theorem of the look-up table 1300″ in FIG. 12 is the same as the look-up table 1300′ in FIG. 11, so the details are not further described.

Referring to FIG. 13, FIG. 13 is a schematic diagram of the look-up table 1300′″ according to another preferred embodiment of the invention. In another preferred embodiment of the invention, if the color areas are obtained by dividing the hue and the saturation in a color space having lightness separated from colors, the look-up table 1300′″ records the at least one first gain, at least one hue H, and at least one saturation S; each of the hues H and each of the saturations S are corresponding to one of the first gains Gnn respectively. The functional theorem of the look-up table 1300′″ in FIG. 13 is the same as the look-up table 1300′ shown in FIG. 11, so the details are not further described.

Referring to FIG. 3 again, after the input image is processed by the image adjusting device 13, the input image will go through the lightness adjusting device 14, the hue adjusting device 16, and the saturation adjusting device 18 to adjust the lightness, the hue, and the saturation respectively. Finally, the input image will be converted back to the original color space (e.g. converted from the Lab color space to the RGB color space) by the color space converting device 10b. The related techniques can be easily achieved by one skilled in the art, so the details are not further described.

Compared with prior art, the image adjusting device of the invention can temporarily change the image parameter (lightness or saturation) of the pixels of an input image according to the user-selected color areas. It allows the user to easily know in which section of the image is the color, included in the selected color area, located within. It is very convenient for the user to adjust an image.

With the above example and explanation, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. An image adjusting device, applied to a display system, for adjusting a first image parameter of a pixel of an input image according to a user-selected color area, the display system comprising a plurality of color areas, a second image parameter of the pixel belonging to one of the color areas, the image adjusting device comprising:
a memory unit for storing at least one first gain and a second gain;
a judgment module for judging whether the user-selected color area is the same as the color area where the second image parameter of the pixel belongs to;
a multiplexer for outputting one of the at least one first gain when the user-selected color area is the same as the color area where the second image parameter of the pixel belongs to and for outputting the second gain when the user-selected color area is different from the color area where the second image parameter of the pixel belongs to; and
a multiplicator for selectively multiplying a value of the first image parameter of the pixel of the input image by the first gain or for multiplying the value of the first image parameter of the pixel of the input image by the second gain.

2. The image adjusting device of claim 1, wherein the first image parameter represents the lightness or the saturation.

3. The image adjusting device of claim 1, wherein the color areas of the display system are obtained by dividing the hue in a color space having lightness separated from colors.

4. The image adjusting device of claim 3, wherein the second image parameter represents the hue.

5. The image adjusting device of claim 4, wherein the memory unit stores a look-up table for recording the at least one first gain and at least one hue, each of the at least one hue is corresponding to one of the at least one first gain respectively.

6. The image adjusting device of claim 5, wherein the multiplexer outputs the first gain corresponding to the hue of the pixel when the user-selected color area is the same as the color area where the hue of the pixel belongs to.

7. The image adjusting device of claim 1, wherein the color areas of the display system are obtained by dividing chroma components in a color space having lightness separated from colors.

8. The image adjusting device of claim 7, wherein the second image parameter comprises a first chroma component and a second chroma component.

9. The image adjusting device of claim 8, wherein the memory unit stores a look-up table for recording the at least one first gain, at least one first chroma component, and at least one second chroma component, each of the at least one first chroma component and each of the at least one second chroma component are corresponding to one of the at least one first gain respectively.

10. The image adjusting device of claim 9, wherein the multiplexer outputs the first gain corresponding to the first chroma component and the second chroma component of the pixel when the user-selected color area is the same as the color area where the first chroma component and the second chroma component of the pixel belong to.

11. The image adjusting device of claim 1, wherein the color areas of the display system are obtained by dividing the hue and saturation in a color space having lightness separated from colors.

12. The image adjusting device of claim 11, wherein the second image parameter comprises the hue and the saturation.

13. The image adjusting device of claim 12, wherein the memory unit stores a look-up table for recording the at least one first gain, at least one hue, and at least one saturation, each of the at least one hue and each of the at least one saturation are corresponding to one of the at least one first gain respectively.

14. The image adjusting device of claim 13, wherein the multiplexer outputs the first gain corresponding to the hue and the saturation of the pixel when the user-selected color area is the same as the color area where the hue and the saturation of the pixel belong to.

15. The image adjusting device of claim 1, wherein each of the at least one first gain is between 0 and 1.

16. The image adjusting device of claim 1, wherein the second gain is set as 1.
